(19) United States
(12) Patent Application Publication
(10) Pub. No.: US 2026/0075926 A1
(43) Pub. Date: Mar. 12, 2026

(54) QUASI-VERTICAL JBS DIODE MONOLITHIC INTEGRATED THREE-PHASE DRU

(71) Applicant: Xidian University, Xi’an (CN)

(72) Inventors: Bin Hou, Xi’an (CN); Xiaohua Ma, Xi’an (CN); Ling Yang, Xi’an (CN); Qingyuan Chang, Xi’an (CN); Youjun Zhu, Xi’an (CN); Hao Lu, Xi’an (CN); Meng Zhang, Xi’an (CN); Mei Wu, Xi’an (CN); Jiale Du, Xi’an (CN); Yue Hao, Xi’an (CN)

(21) Appl. No.: 19/281,756

(22) Filed: Jul. 28, 2025

(30) Foreign Application Priority Data
Sep. 12, 2024 (CN) 2024112792240

(51) Int. Cl. H10D 84/00; H10D 8/01; H10D 8/60; H10D 62/85; H10D 84/01

(52) U.S. Cl. CPC H10D 84/221; H10D 8/051; H10D 8/60; H10D 84/0112; H10D 62/8503

(57) ABSTRACT

A quasi-vertical JBS diode and a monolithic integrated three-phase DRU are provided. The quasi-vertical JBS diode includes a Si substrate, a N+ GaN conductive layer and an N-type GaN drift layer sequentially disposed from bottom to top. A top region of the N-type GaN drift layer defines groove structures distributed concentrically and annularly, and a Mg-doped P-type BN material is disposed on an inside of each of the groove structures and a side of the N-type GaN drift layer. An anode is disposed on a surface of the N-type GaN drift layer defining the groove structures. A cathode is disposed on a surface of the N+ GaN conductive layer at intervals around the N-type GaN drift layer. The monolithic integrated three-phase DRU includes three AC input terminals, two rectified DC output terminals and diode groups corresponding to six rectifier bridge arms. The diodes each are the quasi-vertical JBS diode.

### CROSS-REFERENCE TO RELATED APPLICATION

This application claims priority to Chinese Patent Application No. 202411279224.0, filed on Sep. 12, 2024, which is herein incorporated by reference in its entirety.

### TECHNICAL FIELD

The disclosure relates to the technical field of semiconductors, and more particularly to a quasi-vertical junction barrier Schottky (JBS) diode and a monolithic integrated three-phase diode rectifier unit (DRU).

### BACKGROUND

DRU (diode rectifier unit) is commonly used for conversion of alternating current (AC) and direct current (DC) in a high-power electronic device. In the related art, most power devices still use high-power silicon (Si) single tubes in the form of discrete devices for use in DRU rectifying circuits. However, the use of the discrete devices to form the DRU rectifier circuits results in low integration. With the increasing requirements for the power handling capacity, device miniaturization, and device reliability of rectifying systems, the existing board-level integrated DRU rectifying system will become increasingly difficult to adapt to the needs of the times.

The core component diodes of the existing DRU circuits are predominantly manufactured by using Si-based materials. However, with the increasing requirements for efficiency, power density, and device volume of power processing equipment, the Si-based devices are rapidly approaching the theoretical limits of their intrinsic material properties, resulting in low device power density and difficulty in miniaturization under high-power conditions.

Moreover, a voltage application range of existing small-size DRU circuits is narrow, and the withstand voltage of the core component diode is low, which restricts the performance and development of the DRU.

### SUMMARY

In order to solve the above problems in the related art, the disclosure provides a quasi-vertical JBS diode, a preparation of the quasi-vertical JBS diode, a monolithic integrated three-phase DRU, and a preparation method of the monolithic integrated three-phase DRU. The technical problems to be solved of the disclosure are solved through the following technical solutions.

In the first aspect, embodiments of the disclosure provides a quasi-vertical JBS diode, including a Si substrate, a n-type doping gallium nitride (N+ GaN) conductive layer, an N-type GaN drift layer, an anode and a cathode.

The Si substrate, the N+ GaN conductive layer, and the N-type GaN drift layer are sequentially disposed in that order from bottom to top. A top region of the N-type GaN drift layer defines groove structures distributed concentrically and annularly, and a magnesium-doped (Mg-doped) P-type boron nitride (BN) material is disposed on an inside of each of the groove structures and a side of the N-type GaN drift layer. The anode is disposed on a surface of the N-type GaN drift layer defining the groove structures. The cathode is disposed on a surface of the N+ GaN conductive layer at intervals around the N-type GaN drift layer.

In an embodiment of the disclosure, a doping concentration of Si in the N+ GaN conductive layer is in a range of 1.0×10¹⁸ per cubic centimeters (cm⁻³) to 1.0×10¹⁹ cm⁻³.

In an embodiment of the disclosure, a doping concentration of Si in a non-groove structure part in the N-type GaN drift layer is in a range of 1.8×10¹⁵ cm⁻³ to 1.0×10¹⁷ cm⁻³.

In an embodiment of the disclosure, a doping concentration of Mg in the Mg-doped P-type BN material is in a range of 1.7×10¹⁵ cm⁻³ to 5.0×10¹⁶ cm⁻³.

In an embodiment of the disclosure, a depth of each of the groove structures is in a range of 0.5 microns (μm) to 4 μm, and a distance between each of the groove structures distributed concentrically and annularly is in a range of 1 μm to 2.5 μm.

In the second aspect, the embodiments of the disclosure provide a preparation method of a quasi-vertical JBS diode, configured to prepare the quasi-vertical JBS diode as described in the first aspect. The preparation method of the quasi-vertical JBS diode includes:

obtaining an epitaxial layer structure, where the epitaxial layer structure includes: the Si substrate, the N+ GaN conductive layer and the N-type GaN drift layer from bottom to top;

etching to remove an outer side of the N-type GaN drift layer to obtain a retained N-type GaN drift layer and an exposed N+ GaN conductive layer, so that the retained N-type GaN drift layer and the exposed N+ GaN conductive layer form a first step structure;
etching to remove an outer side of the N+ GaN conductive layer to obtain a retained N+ GaN conductive layer and an exposed Si substrate, so that the retained N+ GaN conductive layer and the exposed Si substrate form a second step structure;
etching the groove structures distributed concentrically and annularly on the top region of the N-type GaN drift layer;
spattering the Mg-doped P-type BN material on the inside of each of the groove structures and the side of the N-type GaN drift layer by a magnetron sputtering process, followed by annealing treatment to obtain an annealed device; and removing excess Mg-doped P-type BN material from a surface of the annealed device;
growing a first passivation layer on all exposed surfaces and sides above an upper surface of the Si substrate; removing the first passivation layer on a surface of the N-type GaN drift layer to define an anode contact opening, and removing the first passivation layer at predetermined positions on two sides of the N+ GaN conductive layer to define a cathode contact opening; and
forming the anode in the anode contact opening by metal evaporation, and forming the cathode with a distance surrounding the N-type GaN drift layer by the metal evaporation in the cathode contact opening.

In the third aspect, the embodiments of the disclosure provide a monolithic integrated three-phase DRU, including a first AC input terminal, a second AC input terminal, a third AC input terminal, a first rectified DC output terminal, a second rectified DC output terminal, and diode groups corresponding to six rectifier bridge arms. The diode groups includes a first phase forward diode group, a first phase reverse diode group, a second phase forward diode group, a second phase reverse diode group, a third phase forward diode group, and a third phase reverse diode group.

The first AC input terminal is connected to an anode input terminal of the first phase forward diode group and a cathode input terminal of the first phase reverse diode group. The second AC input terminal is connected to an anode input terminal of the second phase forward diode group and a cathode input terminal of the second phase reverse diode group. The third AC input terminal is connected to an anode input terminal of the third phase forward diode group and a cathode input terminal of the third phase reverse diode group. The first rectified DC output terminal is connected to a cathode input terminal of the first phase forward diode group, a cathode input terminal of the second phase forward diode group and a cathode input terminal of the third phase forward diode group. The second rectified DC output terminal is connected to an anode input terminal of the first phase reverse diode group, an anode input terminal of the second phase reverse diode group and an anode input terminal of the third phase reverse diode group. Diodes in each of the diode groups are connected in series in a same direction, and are the same in number, each of the diodes in each of the diode groups is a quasi-vertical JBS diode, and a preparation method of the quasi-vertical JBS diode is the preparation method of the quasi-vertical JBS diode as described in the second aspect.

In an embodiment of the disclosure, a working process of the monolithic integrated three-phase DRU includes:
in each cycle, according to a three-phase AC waveform input by the first AC input terminal, the second AC input terminal and the third AC input terminal, and a circuit conducting state, rectifying input-side AC voltage into output-side DC voltage by using simultaneously conducted diode groups in each of six conduction intervals, and outputting the output-side DC voltage through the first rectified DC output terminal and the second rectified DC output terminal; where each of the six conduction intervals has two diode groups with mutually positive and negative polarity.

In an embodiment of the disclosure, in each of the six conduction intervals, the simultaneously conducted diode groups includes the follows.

In a first conduction interval T1, the first phase forward diode group and the third phase reverse diode group conduct. In a second conduction interval T2, the second phase forward diode group and the third phase reverse diode group conduct. In a third conduction interval T3, the second phase forward diode group and the first phase reverse diode group conduct. In a fourth conduction interval T4, the third phase forward diode group and the first phase reverse diode group conduct. In a fifth conduction interval T5, the third phase forward diode group and the second phase reverse diode group conduct. In a sixth conduction interval T6, the first phase forward diode group and the second phase reverse diode group conduct.

In the fourth aspect, the embodiments of the disclosure provide a preparation method of a monolithic integrated three-phase DRU, configured to prepare the monolithic integrated three-phase DRU as described in the third aspect. The preparation method of the monolithic integrated three-phase DRU includes:
acquiring multiple prepared quasi-vertical JBS diodes on a same Si substrate to obtain a multi-device structure; where each of the multiple quasi-vertical JBS diodes is prepared by the preparation method of the quasi-vertical JBS diodes;
growing a second passivation layer on all exposed surfaces and sides of the multi-device structure on the Si substrate, opening first holes by etching the second passivation layer, performing the metal evaporation on the first holes, and forming a first layer of metal interconnects according to an electrode connection requirement of the multiple quasi-vertical JBS diodes of the monolithic integrated three-phase DRU; and
growing a third passivation layer, opening second holes by etching the third passivation layer, performing the metal evaporation on the second holes, and forming a second layer of metal interconnects according to the electrode connection requirement of the multiple quasi-vertical JBS diodes of the monolithic integrated three-phase DRU.

The beneficial effects of the disclosure are as follows.

The diodes of the embodiments of the disclosure use the Si-based GaN material to reduce circuit cost, and use grooves filled with the Mg-doped P-type BN material on a Si-based GaN substrate to ensure that the diode forms a JBS structure. The embodiments of the disclosure replace the traditional Schottky diode with a quasi-vertical diode improved with Mg-doped P-type BN JBS technology, and utilizes the high breakdown field strength of the BN material, the electric field regulation capability of the JBS ring structure, and the suppression effect of P-BN covering the device sidewall on sidewall leakage current, which can improve the withstand voltage value of the diode.

The monolithic integrated three-phase DRU provided on this basis achieves an improvement in integration, greatly reduces the circuit volume, and can improve circuit reliability. Existing devices mostly use Si devices, while GaN devices can work stably under more complex working conditions compared to the Si devices. The excellent electrical properties and stability of the GaN devices are considered to be suitable for applications in high frequency, high power, strong radiation and other occasions. In the disclosure, the Si-based GaN quasi-vertical JBS diode based on the P-BN technology utilizes the high breakdown field strength of the BN material and the electric field regulation capability of the JBS structure to greatly improve the withstand voltage level of the Schottky diode, broaden the voltage application window of the miniaturized DRU three-phase rectifier circuit, which can enhance the power handling capacity of the DRU rectifying circuit. However, the related art mostly uses traditional Schottky diodes, lacks effective junction termination technology to increase the operating voltage of the device, and limits the working range of the existing devices.

### BRIEF DESCRIPTION OF DRAWINGS

FIG. 1 illustrates a schematic structural diagram of a quasi-vertical JBS diode according to an embodiment of the disclosure.

FIG. 2 illustrates a schematic sectional diagram of the quasi-vertical JBS diode according to an embodiment of the disclosure.

FIG. 3 illustrates a schematic longitudinal sectional diagram of the quasi-vertical JBS diode according to an embodiment of the disclosure.

FIG. 4 illustrates a flowchart of a preparation method of a quasi-vertical JBS diode according to an embodiment of the disclosure.

FIGS. 5a-5j illustrate schematic diagrams of a process of the preparation method of the quasi-vertical JBS diode according to an embodiment of the disclosure.

FIG. 6 illustrates a schematic diagram of a circuit principle of a monolithic integrated three-phase DRU according to an embodiment of the disclosure.

FIG. 7 illustrates a three-dimensional (3D) schematic diagram of an entire circuit used by the monolithic integrated three-phase DRU according to an embodiment of the disclosure.

FIG. 8 illustrates a 3D schematic diagram from a top perspective of the entire circuit used by the monolithic integrated three-phase DRU according to an embodiment of the disclosure.

FIG. 9 illustrates a schematic diagram of conduction states of the entire circuit used by the monolithic integrated three-phase DRU at different intervals according to an embodiment of the disclosure.

FIG. 10 illustrates a schematic diagram of a conduction state of diodes of the entire circuit used by the monolithic integrated three-phase DRU in a first conduction interval T1 according to an embodiment of the disclosure.

FIG. 11 illustrates a schematic diagram of an entire output of the entire circuit used by the monolithic integrated three-phase DRU according to an embodiment of the disclosure.

FIG. 12 illustrates a flowchart of a preparation method of a monolithic integrated three-phase DRU according to an embodiment of the disclosure.

FIGS. 13a-13g illustrate schematic diagrams of a process of the preparation method of the monolithic integrated three-phase DRU according to an embodiment of the disclosure.

### DETAILED DESCRIPTION OF EMBODIMENTS

The disclosure is further described in detail in conjunction with embodiments below, but the embodiments of the disclosure are not limited by these.

At present, the third-generation semiconductor materials such as GaN have excellent electrical properties such as large bandgap, high critical breakdown electric field, high saturation velocity, good thermal conductivity, high-temperature resistance and corrosion resistance compared to Si-based materials, and are considered to be suitable for applications in high frequency, high power, strong radiation and other occasions. In recent years, thanks to excellent characteristics such as low saturation velocity, low breakdown voltage, low inversion layer mobility and high device resistance, GaN-based power devices have developed rapidly and have been widely used in power systems. However, with the increasing requirements for the power handling capacity and the device miniaturization of rectifying systems, and the diversification of usage scenarios proposes higher and higher requirements on the reliability of the circuit system, the industry has been calling for integrated GaN power modules. Compared with traditional GaN integrated circuits, Si-based GaN monolithic integrated circuits have smaller size, smaller parasitics, higher power density, lower cost and higher reliability, enabling them to be used in high-power electronic conversion systems with complex working conditions and limited volume, such as inverters, AC/DC bridges, DC/DC bridges, and traction modules.

Therefore, the disclosure considers designing a DRU using Si-based GaN to solve the aforementioned defects of the existing DRU.

In order to achieve the above purpose, the embodiments of the disclosure provide a quasi-vertical JBS diode, a preparation of the quasi-vertical JBS diode, a monolithic integrated three-phase DRU, and a preparation method of the monolithic integrated three-phase DRU.

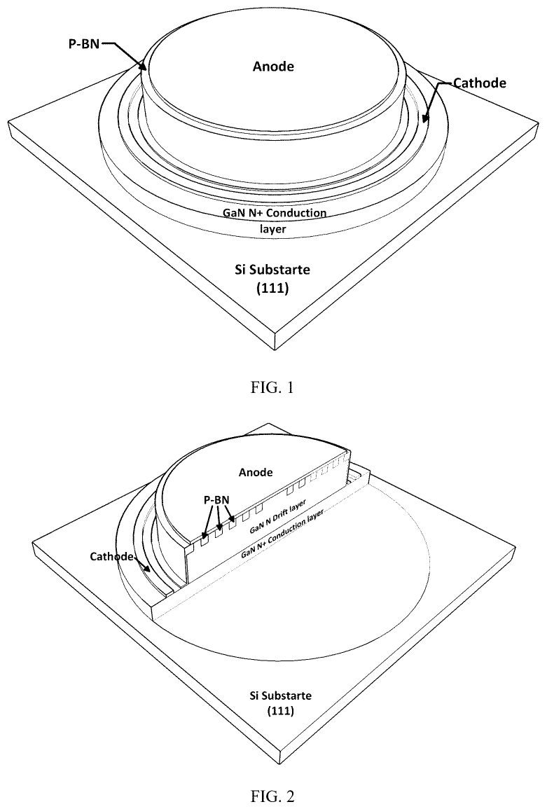

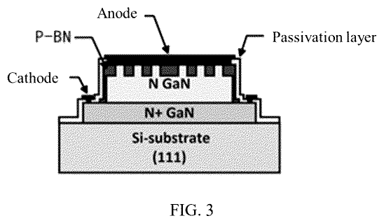

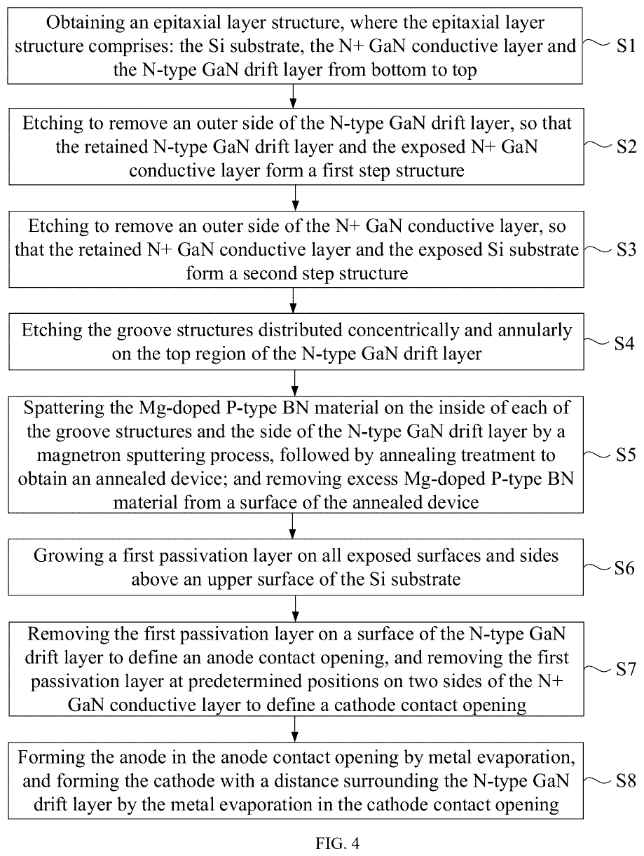

In the first aspect, the embodiments of the disclosure provides a quasi-vertical JBS diode, referring to a schematic front diagram of the quasi-vertical JBS diode as shown in FIG. 1, a schematic sectional diagram of the quasi-vertical JBS diode as shown in FIG. 2, and a schematic longitudinal sectional diagram of the quasi-vertical JBS diode as shown in FIG. 3, the quasi-vertical JBS diode includes a Si substrate, a N+ GaN conductive layer, an N-type GaN drift layer, an anode and a cathode.

The Si substrate, the N+ GaN conductive layer, and the N-type GaN drift layer are sequentially disposed in that order from bottom to top. A top region of the N-type GaN drift layer defines groove structures distributed concentrically and annularly, and a Mg-doped P-type BN material is disposed on an inside of each of the groove structures and a side of the N-type GaN drift layer. The anode is disposed on a surface of the N-type GaN drift layer defining the groove structures. The cathode is disposed on a surface of the N+ GaN conductive layer at intervals around the N-type GaN drift layer.

Specifically, in FIG. 1 to FIG. 3, Si Substrate represents the Si substrate. N+ GaN and GaN N+ conductive layer each represent the N+ GaN conductive layer. N GaN and GaN N drift layer each represent the N-type GaN drift layer. P-BN represents the Mg-doped P-type BN material. Anode represents the anode. Cathode represents the cathode.

Specifically, the Si substrate can adopt a 111-crystal plane.

The N+ GaN conductive layer is located on an upper surface of the Si substrate, and is a cylindrical structure. A thickness of the N+ GaN conductive layer can be set according to needs, for example, may be in a range of 0.6 μm to 1 μm. In an optional embodiment, a doping concentration of Si in the N+ GaN conductive layer is in a range of 1.0×10¹⁸ cm⁻³ to 1.0×10¹⁹ cm⁻³. It can be understood that, in general, the higher the doping concentration, the lower the cathode electrode contact resistance, and finally the overall on-resistance will be smaller after the device is conducted. However, excessive doping concentration may reduce the device withstand voltage to a certain extent, so it needs to be reasonably selected according to demand.

The N-type GaN drift layer is located on a center region of an upper surface of the N+ GaN conductive layer, which is a cylindrical structure. A thickness of the N-type GaN drift layer can be set according to needs, for example, may be in a range of 3 μm to 5 μm.

The top region of the N-type GaN drift layer defines groove structures distributed concentrically and annularly. Please refer to FIG. 2 for understanding, each groove structure is an annular groove structure. The sizes of the groove structures are nested and concentrically distributed. The number of the annular groove structures can be determined according to the flow requirements, and a single ring or multiple rings are both possible.

A depth of each black block in FIG. 2 indicates a depth of each annular groove structure, and a width of the black block indicates a width of the circular ring of the annular groove structure. The depth of each groove structure is less than the thickness of the N-type GaN drift layer. In an optional embodiment, the depth of each groove structure can be in a range of 0.5 μm to 4 μm. In general, reducing the distance between the groove structures can enhance the reverse withstand voltage of the device, but it will correspondingly sacrifice a forward conduction area of the device, causing the conduction ability of the device to decrease, thus it needs to be reasonably set. In an optional embodiment, the distance between the concentric annular groove structures can be in a range of 1 μm to 2.5 μm.

In an optional embodiment, a doping concentration of Si in a non-groove structure part in the N-type GaN drift layer is in a range of 1.8×10¹⁵ cm⁻³ to 1.0×10¹⁷ cm⁻³. This doping concentration will also affect the device withstand voltage. Theoretically, the lower the doping concentration, the higher the device withstand voltage. It will also affect the forward conduction characteristics of the device. The lower the doping concentration, the greater the forward conduction resistance. Therefore, this value needs to be considered together with the doping concentration of Si in the N+ GaN conductive layer and the doping concentration of Mg of the P-BN.

The Mg-doped P-type BN material is disposed on an inside of each groove structure and a side of the N-type GaN drift layer. As shown in FIG. 3, the Mg-doped P-type BN material not only fills the inside of each groove structure, but are also disposed on the side of the N-type GaN drift layer, and extend to a surface of a part of the N+ GaN conductive layer at an interface between the N+ GaN conductive layer and the N-type GaN drift layer. The doping concentration of Mg in the Mg-doped P-type BN material will affect the depletion capability of the P-BN ring in the reverse direction. In an optional embodiment, the doping concentration of Mg in the Mg-doped P-type BN material is in a range of 1.7×10¹⁵ cm⁻³ to 5.0×10¹⁶ cm⁻³.

The anode is disposed on the surface of the N-type GaN drift layer defining the groove structures.

The cathode is disposed on the surface of the N+ GaN conductive layer at intervals around the N-type GaN drift layer. It can be seen from FIG. 1 and FIG. 2 that the cathode is also in a circular ring shape.

It should be noted that, for a quasi-vertical JBS diode used alone, the passivation layer shown in FIG. 3 may not be retained.

The diodes in the embodiments of the disclosure all adopt a quasi-vertical diode structure. Unlike traditional vertical devices where current is only transported vertically and the anode and cathode are respectively on the front and back of the wafer, the anode and cathode of the quasi-vertical device are on the same surface (as shown in FIGS. 1 and 2). Such a quasi-vertical structure facilitates the subsequent use of on-chip wiring to connect the devices and complete the circuit construction.

The diodes of the embodiments of the disclosure use the Si-based GaN materials to reduce circuit cost, and use grooves filled with the Mg-doped P-type BN material on a Si-based GaN substrate to ensure that the diode forms a JBS structure. The embodiments of the disclosure replace the traditional Schottky diode with a quasi-vertical diode improved with Mg-doped P-type BN JBS technology, and utilizes the high breakdown field strength of the BN material, the electric field regulation capability of the JBS ring structure, and the suppression effect of P-BN covering the device sidewall on sidewall leakage current, which can improve the withstand voltage value of the diode. When the proposed quasi-vertical JBS diode is used to construct a monolithic integrated three-phase DRU, the power processing capacity of the DRU rectifying circuit can be enhanced.

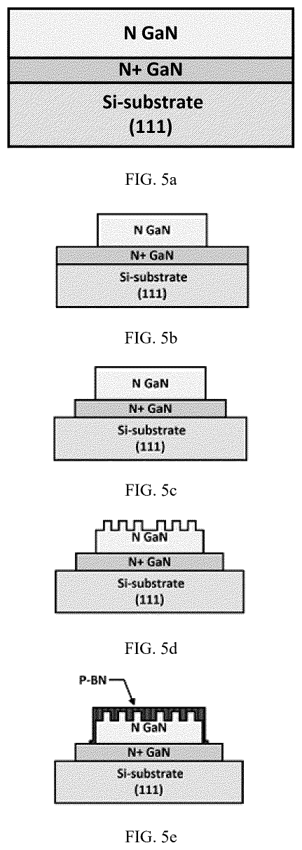

In the second aspect, the embodiments of the disclosure provide a preparation method of a quasi-vertical JBS diode, configured to prepare the quasi-vertical JBS diode as described in the first aspect. As shown in FIG. 4, The preparation method of the quasi-vertical JBS diode includes the following steps S1-S8.

In S1, an epitaxial layer structure is obtained. The epitaxial layer structure includes a Si substrate, a N+ GaN conductive layer and a N-type GaN drift layer from bottom to top.

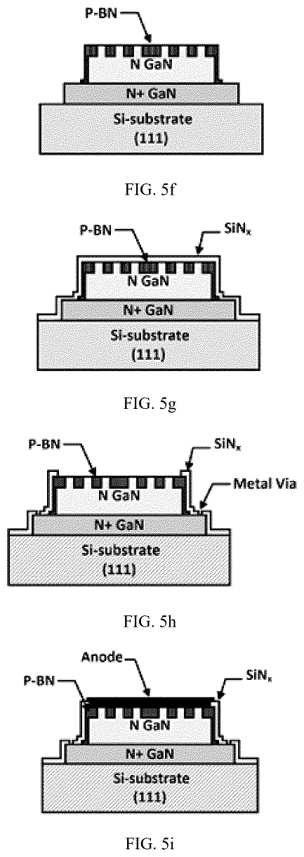

The epitaxial layer structure can be understood referring to FIG. 5a. Si Substrate represents the Si substrate; N+ GaN represents the N+ GaN conductive layer; and N GaN represents the N-type GaN drift layer.

The Si substrate can adopt a 111-crystal plane. A doping concentration of Si in the N+ GaN conductive layer can be in a range of 1.0×10¹⁸ cm⁻³ to 1.0×10¹⁹ cm⁻³. A doping concentration of Si in the N-type GaN drift layer can be in a range of 1.8×10¹⁵ cm⁻³ to 1.0×10¹⁷ cm⁻³.

In S2, an outer side of the N-type GaN drift layer is removed by etching, so that the retained N-type GaN drift layer and the exposed N+GaN conductive layer form a first step structure.

The step is to achieve mesa etching, the N-type GaN drift layer at the outer side is etched downwards to expose the N+ GaN conductive layer. It can be understood that the retained N-type GaN drift layer is still a cylindrical structure. An etching depth is over 4 μm. Specifically, chlorine-based (Cl-based) inductive coupling (ICP) can be adopted for etching, and etching gases are mainly Cl₂ and boron chlorine (BCl₃). Specifically, BCl₃ is a sidewall protective gas, which can effectively improve the selectivity and improve the etching morphology. The etching power adopts fast etching conditions, a source power is in a range of 120 watts (W) to 160 W, a bias power is in a range of 45 W to 60 W, and a cavity pressure is controlled in a range of 4 millitorrs (mt) to 7 mt. The device structure formed in this step is shown in FIG. 5b.

In S3, an outer side of the N+ GaN conductive layer is removed by etching, so that the retained N+ GaN conductive layer and the exposed Si substrate form a second step structure.

The step is to achieve isolation etching of an active region. Specifically, the outer side of the N+ GaN conductive layer is etched downwards to expose the Si substrate. It can be understood that the retained N+ GaN conductive layer is still a cylindrical structure. The etching conditions for the step are consistent with S2, and an etching depth is 1 μm. The device structure formed in this step is shown in FIG. 5c.

In S4, the groove structures distributed concentrically and annularly are etched on the top region of the N-type GaN drift layer.

The step is to etch an anode region P-type groove through the Cl-based ICP etching. However, since the conduction region has higher requirements on etching damage than the mesa, only a smaller etching power can be used. The source power is in a range of 35 W to 50 W, the bias power is below 20 W, but not less than 13 W, and the cavity pressure is controlled in a range of 4 mt to 6 mt. The etched groove structures are distributed concentrically and annularly, and a depth of each groove structure is less than that of the N-type GaN drift layer. The depth of each groove structure is in a range of 0.5 μm to 4 μm, and a distance between the groove structures is in a range of 1 μm to 2.5 μm. The device structure formed in this step is shown in FIG. 5d.

In S5, the Mg-doped P-type BN material is spattered on the inside of each groove structure and the side of the N-type GaN drift layer by a magnetron sputtering process, followed by annealing treatment to obtain an annealed device. Excess Mg-doped P-type BN material is removed from a surface of the annealed device.

The P-type BN material (P-BN) is spattered on the inside of the groove structure and the side of the N-type GaN drift layer, and thermal annealing is performed to activate the impurities. Specifically, dual-target radio frequency (RF) magnetron sputtering is used to grow the P-BN layer. The chamber pressure is in a range of 4 mt to 5 mt, the sputtering gas is argon (Ar), and the sputtering power is in a range of 150 W to 160 W. The sputtering depth needs to be adjusted according to the depth of the groove structure and needs to be slightly larger than the etching depth of the groove structure. After sputtering, annealing is performed at 1100-1200 Celsius degrees (° C.) for 10 minutes (min) to activate Mg impurities, thereby forming Mg-doped P-type BN material inside the groove structure and on the side of the N-type GaN drift layer, as shown in FIG. 5e.

Then the excess Mg-doped P-type BN material beyond the surface of the groove structure is etched away, as shown in FIG. 5f. Specifically, fluorine (F)-based ICP etching is mainly used, and the main etching gases are sulfur fluoride (SF₆), carbon tetrafluoride (CF₄), and trifluoromethane (CHF₃). Since BN etching is more difficult, the power used for etching is relatively large, the source power is in a range of 180 W to 200 W, and the bias power is in a range of 65 W to 77 W. Due to the high selectivity of F-based etching for GaN materials, the etching can be set to an over-etching amount greater than 30% of the target depth to ensure that the BN region that needs to be etched can be etched cleanly, while also minimizing the etching of GaN materials.

The result is shown in FIG. 5f, the Mg-doped P-type BN material is distributed inside the groove structures and the side of the N-type GaN drift layer, and extends to a part surface of the N+ GaN conductive layer.

In S6, a first passivation layer is grown on all exposed surfaces and sides above an upper surface of the Si substrate.

Referring to FIG. 5g, on the entire upper surface and side of the device excluding the side of the Si substrate, a silicon nitride (SiN) passivation layer (see SiNₓ in FIG. 5g) is grown by using a plasma enhanced chemical vapor deposition (PECVD) device, with a target thickness of about 120 nanometers (nm), reaction gases of silane (SiH₄) and ammonia (NH₃), and a carrier gas of helium (He), and the growth is carried out at a pressure of 600 mt and 250° C. In order to distinguish it from the monolithic integrated three-phase DRU in the following text, the passivation layer here can be called the first passivation layer.

In S7, the first passivation layer on a surface of the N-type GaN drift layer is removed to define an anode contact opening, and the first passivation layer at predetermined positions on two sides of the N+ GaN conductive layer is removed to define a cathode contact opening.

Please refer to FIG. 5h for understanding this step. The anode contact opening is the entire surface of the N-type GaN drift layer, and the cathode contact opening is on both sides of the N+ GaN conductive layer and has a spacing with the N-type GaN drift layer.

Specifically, the formation of through holes requires F-based ICP etching to remove the SiN layer in the opening region. In order to ensure that the metal contact region is etched cleanly, at least 40% to 50% over etching is required.

In S8, an anode is formed in the anode contact opening by metal evaporation, and a cathode with a certain distance surrounding the N-type GaN drift layer is formed by the metal evaporation in the cathode contact opening.

Specifically, referring to FIG. 5i, for the anode Schottky contact, metal nickel/gold (Ni/Au) is evaporated and then annealed to form the anode. The metal layer is formed by evaporation, the thickness adopts the thick gate condition Ni/Au=45/400 (nm), and the metal pattern is formed by metal stripping. The annealing condition after stripping is nitrogen (N₂) environment, annealing at 860° C. for 60 seconds(s).

Specifically, referring to FIG. 5j, for the cathode ohmic contact, metal titanium/aluminum nickel/gold (Ti/Al/Ni/Au) is evaporated to form the cathode. The metal layer is formed by using the same evaporation method, and a thickness of each layer is Ti/Al/Ni/Au=200/1600/550/450 angstroms (Å).

In this way, a quasi-vertical JBS diode is finally formed. When the quasi-vertical JBS diode is used alone, the passivation layer can be removed. When other devices still need to be interconnected later, the passivation layer is retained.

As aforementioned, the diode of the embodiment of the disclosure grows Mg-doped P-type BN material on a Si-based GaN substrate by using grooves, which can reduce circuit costs while ensuring that the diode forms a quasi-vertical JBS structure, thereby improving the withstand voltage value of the diode.

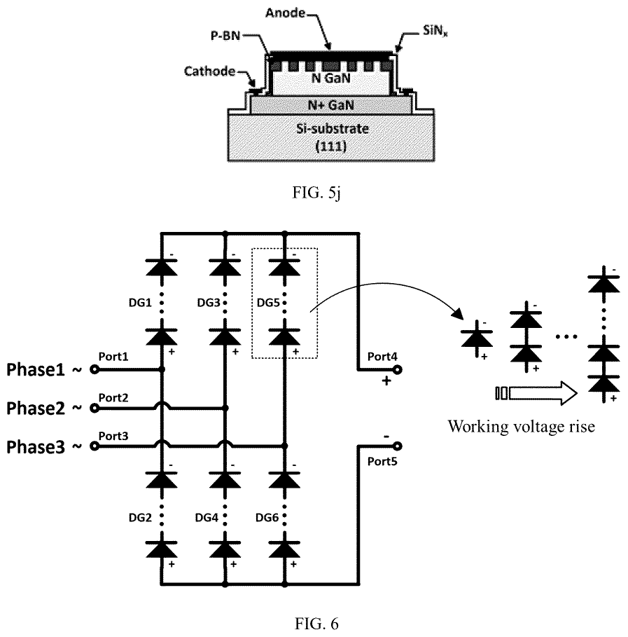

In the third aspect, on the basis of the provided quasi-vertical JBS diode, the embodiments of the disclosure provide a monolithic integrated three-phase DRU, referring to FIG. 6, the monolithic integrated three-phase DRU includes a first AC input terminal Port1, a second AC input terminal Port2, a third AC input terminal Port3, a first rectified DC output terminal Port4, a second rectified DC output terminal Port5, and diode groups corresponding to six rectifier bridge arms. The diode groups includes a first phase forward diode group DG1, a first phase reverse diode group DG2, a second phase forward diode group DG3, a second phase reverse diode group DG4, a third phase forward diode group DG5, and a third phase reverse diode group DG6.

The first AC input terminal Port1 is connected to an anode input terminal of the first phase forward diode group DG1 and a cathode input terminal of the first phase reverse diode group DG2. The second AC input terminal Port2 is connected to an anode input terminal of the second phase forward diode group DG3 and a cathode input terminal of the second phase reverse diode group DG4. The third AC input terminal Port3 is connected to an anode input terminal of the third phase forward diode group DG5 and a cathode input terminal of the third phase reverse diode group DG6. The first rectified DC output terminal Port4 is connected to a cathode input terminal of the first phase forward diode group DG1, a cathode input terminal of the second phase forward diode group DG3 and a cathode input terminal of the third phase forward diode group DG5. The second rectified DC output terminal Port5 is connected to an anode input terminal of the first phase reverse diode group DG2, an anode input terminal of the second phase reverse diode group DG4 and an anode input terminal of the third phase reverse diode group DG6. Diodes in each of the diode groups are connected in series in a same direction, and are the same in number, each of the diodes in each of the diode groups is a quasi-vertical JBS diode, and a preparation method of the quasi-vertical JBS diode is the preparation method of the quasi-vertical JBS diode as described in the second aspect.

Specifically, each diode group corresponds to a rectifier bridge arm. The number of the diodes in each diode group can be adjusted according to system capacity requirements, with a minimum of one, but the number of diodes in each diode group is the same. The diodes in each diode group satisfy the same-direction series connection relationship, that is, the cathode of the previous diode is connected to the anode of the next diode.

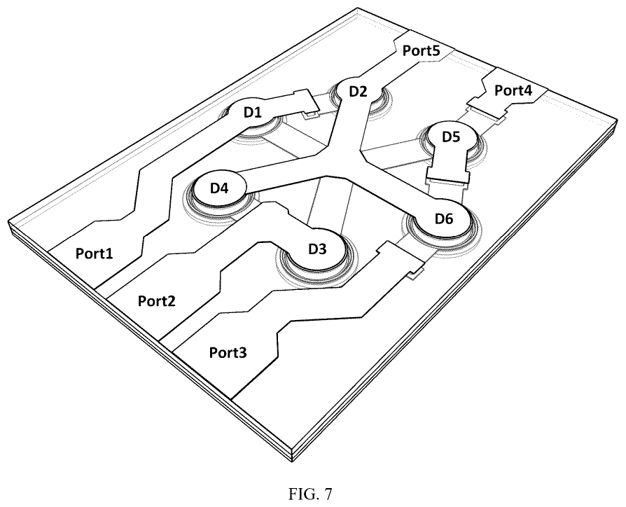

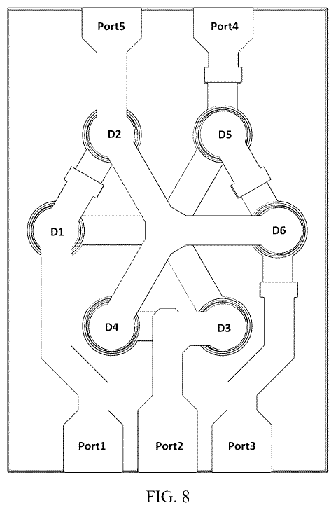

FIG. 7 illustrates a 3D schematic diagram of an entire circuit used by the monolithic integrated three-phase DRU, and FIG. 8 illustrates a 3D schematic diagram from a top perspective of the entire circuit used by the monolithic integrated three-phase DRU. Specifically, port 1 to port 3 are respectively Port1 to Port3, port 4 to port 5 are respectively Port4 to Port 5, and D1 to D6 are respectively DG1 to DG6. The light-colored connecting lines correspond to the first layer, and the dark-colored connecting lines correspond to the second layer. Please refer to FIG. 7 and FIG. 8 for the connection relationship of each diode group in the first layer or the second layer, and no one-to-one explanation will be given here.

A basic structure unit of the three-phase DRU proposed by the embodiments of the disclosure is the six rectifier bridge arms, and each bridge arm is mainly composed of high-power diodes connected in series (all of which are quasi-vertical JBS diodes provided in the first aspect). DRU is essentially a grid-commutated converter, which requires the connected AC system to provide a stable commutation voltage. Then the six rectifier bridge arms conduct in sequence to rectify the input-side AC voltage into the output-side DC voltage. A topological structure and an operation principle of DRU are very similar to a line-commutated converter (LCC) used in a converter station of the traditional high-voltage DC transmission system. The main difference is that a thyristor used in LCC is a semi-controlled device and needs to be configured with a corresponding phase-controlled trigger unit, while the high-power diode used in DRU is an uncontrollable device. DRU can only realize rectification operation, but does not need to receive a trigger control signal during operation, and does not need to configure additional control equipment.

Specifically, a working process of the monolithic integrated three-phase DRU includes the follows.

In each cycle, according to a three-phase AC waveform input by the first AC input terminal Port1, the second AC input terminal Port2 and the third AC input terminal Port3, and a circuit conducting state, input-side AC voltage is rectified into output-side DC voltage by using simultaneously conducted diode groups in each of six conduction intervals, and the output-side DC voltage is output through the first rectified DC output terminal Port4 and the second rectified DC output terminal Port5. Each conduction interval has two diode groups with mutually positive and negative polarity.

Specifically, a three-phase AC waveform of one cycle can be roughly divided into six conduction intervals T1-T6 according to the circuit conduction state. In each interval, there are only two diode groups with mutually positive and negative polarity simultaneously conduct.

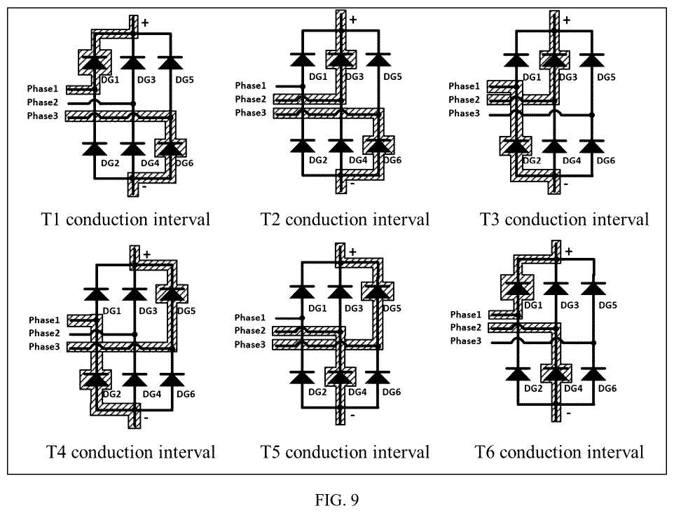

Please refer to the shaded region in FIG. 9, in the six conduction intervals, the simultaneously conducted diode groups include the follows.

In a first conduction interval T1, the first phase forward diode group DG1 and the third phase reverse diode group DG6 conduct. In a second conduction interval T2, the second phase forward diode group DG3 and the third phase reverse diode group DG6 conduct. In a third conduction interval T3, the second phase forward diode group DG3 and the first phase reverse diode group DG2 conduct. In a fourth conduction interval T4, the third phase forward diode group DG5 and the first phase reverse diode group DG2 conduct. In a fifth conduction interval T5, the third phase forward diode group DG5 and the second phase reverse diode group DG4 conduct. In a sixth conduction interval T6, the first phase forward diode group DG1 and the second phase reverse diode group DG4 conduct.

The conduction intervals represented by T1 to T6 are different time segments.

Specifically, in the first conduction interval T1, since a phase 1 has the highest voltage, the forward diode group of the phase 1, namely the first phase forward diode group DG1, conducts, the forward diode groups of other two phases, namely the second phase forward diode group DG3 and the third phase forward diode group DG5, are in the reverse cut-off state and do not conduct since voltages of the corresponding phase 2 and phase 3 are less than the input voltage of the phase 1. Since the phase 3 has the highest reverse voltage at this time, the reverse diode group of the phase 3, namely the third phase reverse diode group DG6, conducts, and the reverse diode groups of the other two phases, namely the first phase reverse diode group DG2 and the second phase reverse diode group DG4, do not conduct. At this time, for the output terminal, the DC positive polarity output voltage is the voltage of the phase 1, the DC negative polarity output voltage is the voltage of the phase 3, and the overall output voltage is an absolute value of the voltage difference between the phase 1 and the phase 3.

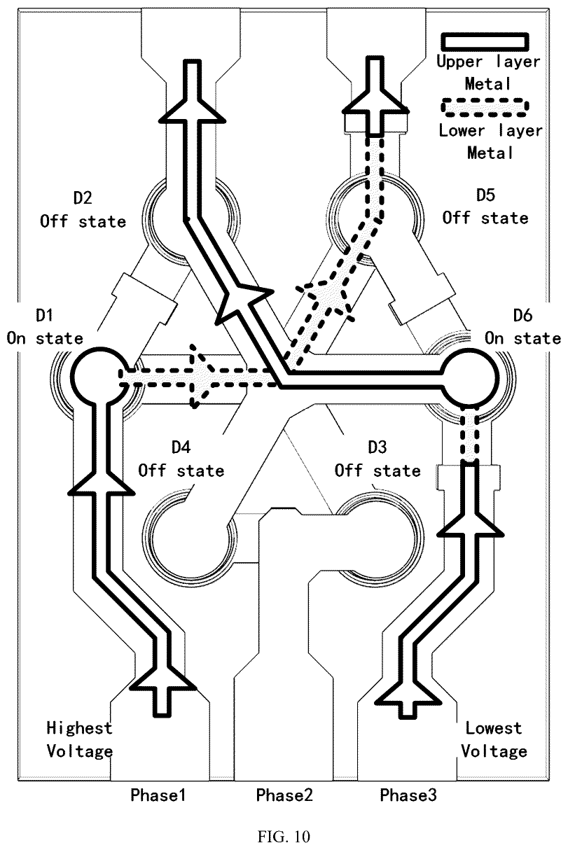

Based on FIG. 8, the conduction state of the diodes in the first conduction interval T1 is shown in FIG. 10.

In the second conduction interval T2, since the phase 2 has the highest voltage, the forward diode group of the phase 2, namely the second phase forward diode group DG3, conducts, the forward diode groups of other two phases, namely the first phase forward diode group DG1 and the third phase forward diode group DG5, do not conduct since anode voltages of the phase 1 and the phase 3 are less than the input voltage of the phase 2. Since the phase 3 has the highest reverse voltage, at this time, the reverse diode group of the phase 3, namely the third phase reverse diode group DG6, conducts, and the reverse diode groups of the other two phases, namely the first phase reverse diode group DG2 and the second phase reverse diode group DG4, do not conduct. At this time, for the output terminal, the DC positive polarity output voltage is the voltage of the phase 2, and the DC negative polarity output voltage is the voltage of the phase 3.

In the third conduction interval T3, since the phase 2 has the highest voltage, the forward diode group of the phase 2, namely the second phase forward diode group DG3, conducts, the forward diode groups of other two phases, namely the first phase forward diode group DG1 and the third phase forward diode group DG5, do not conduct since the anode voltages of the phase 1 and the phase 3 are less than the input voltage of the phase 2. Since the phase 1 has the highest reverse voltage, at this time, the first phase reverse diode group DG2 conducts, and the reverse diode groups of the other two phases, namely the second phase reverse diode group DG4 and the third phase reverse diode group DG6, do not conduct. At this time, for the output terminal, the DC positive polarity output voltage is the voltage of the phase 2, and the DC negative polarity output voltage is the voltage of the phase 1.

In the fourth conduction interval T4, since the phase 3 has the highest voltage, the forward diode group of the phase 3, namely the third phase forward diode group DG5, conducts, the forward diode groups of other two phases, namely the first phase forward diode group DG1 and the second phase forward diode group DG3, do not conduct since the anode voltages of the phase 2 and the phase 3 are less than the input voltage of the phase 1. Since the phase 1 has the highest reverse voltage, at this time, the first phase reverse diode group DG2 conducts, and the reverse diode groups of the other two phases, namely the second phase reverse diode group DG4 and the third phase reverse diode group DG6, do not conduct. At this time, for the output terminal, the DC positive polarity output voltage is the voltage of the phase 3, and the DC negative polarity output voltage is the voltage of the phase 1.

In the fifth conduction interval T5, since the phase 3 has the highest voltage, the forward diode group of the phase 3, namely the third phase forward diode group DG5, conducts, the forward diode groups of other two phases, namely the first phase forward diode group DG1 and the second phase forward diode group DG3, do not conduct since the anode voltages of the phase 1 and the phase 2 are less than the input voltage of the phase 3. Since the phase 2 has the highest reverse voltage, at this time, the second phase reverse diode group DG4 conducts, and the reverse diode groups of the other two phases, namely the first phase reverse diode group DG2 and the third phase reverse diode group DG6, do not conduct. At this time, for the output terminal, the DC positive polarity output voltage is the voltage of the phase 3, and the DC negative polarity output voltage is the voltage of the phase 2.

In the sixth conduction interval T6, since the phase 1 has the highest voltage, the forward diode group of the phase 1, namely the first phase forward diode group DG1, conducts, the forward diode groups of other two phases, namely the second phase forward diode group DG3 and the third phase forward diode group DG5, do not conduct since the anode voltages of the phase 2 and the phase 3 are less than the input voltage of the phase 1. Since the phase 2 has the highest reverse voltage, at this time, the second phase reverse diode group DG4 conduct, and the reverse diode groups of the other two phases, namely the first phase reverse diode group DG2 and the third phase reverse diode group DG6, do not conduct. At this time, for the output terminal, the DC positive polarity output voltage is the voltage of the phase 1, and the DC negative polarity output voltage is the voltage of the phase 2.

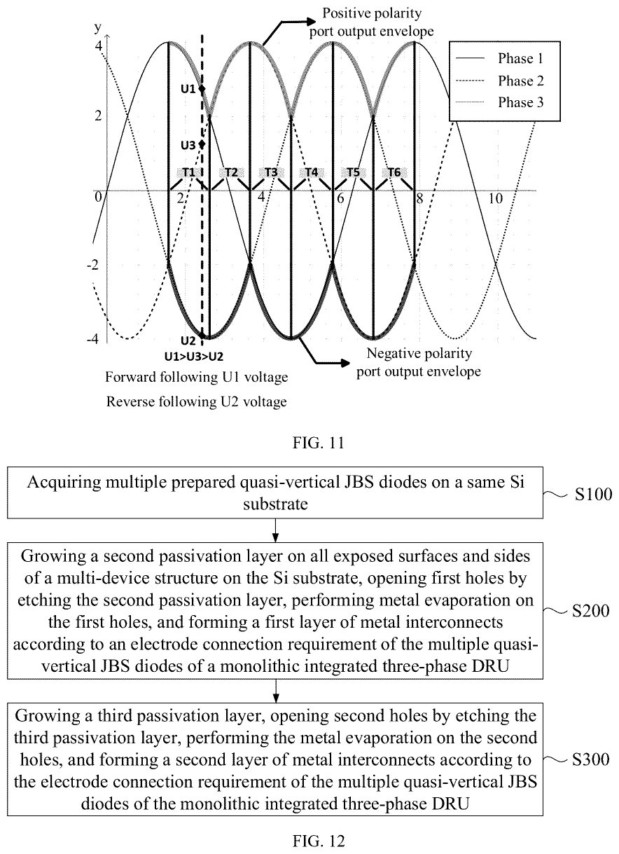

The final DC output waveform is a difference between a maximum and a minimum of the positive and negative voltages at each moment, that is, the voltage envelope, which can be understood by referring to FIG. 11. The above six conduction processes, specific waveforms, and the conduction state in each time interval are shown in FIG. 9.

The monolithic integrated three-phase DRU provided by the embodiments of the disclosure is achieved based on the provided quasi-vertical JBS diode, which achieves an improvement in integration, greatly reduces the circuit volume, and can improve circuit reliability. Existing devices mostly use Si devices, while GaN devices can work stably under more complex working conditions compared to the Si devices. The excellent electrical properties and stability of the GaN devices are considered to be suitable for applications in high frequency, high power, strong radiation and other occasions. In the disclosure, the Si-based GaN quasi-vertical JBS diode based on the P-BN technology utilizes the high breakdown field strength of the BN material and the electric field regulation capability of the JBS structure to greatly improves the withstand voltage level of the Schottky diode, and broaden the voltage application window of the miniaturized DRU three-phase rectifier circuit. However, the related art mostly uses traditional Schottky diodes, lacks effective junction termination technology to increase the operating voltage of the device, and limits the working range of the existing devices.

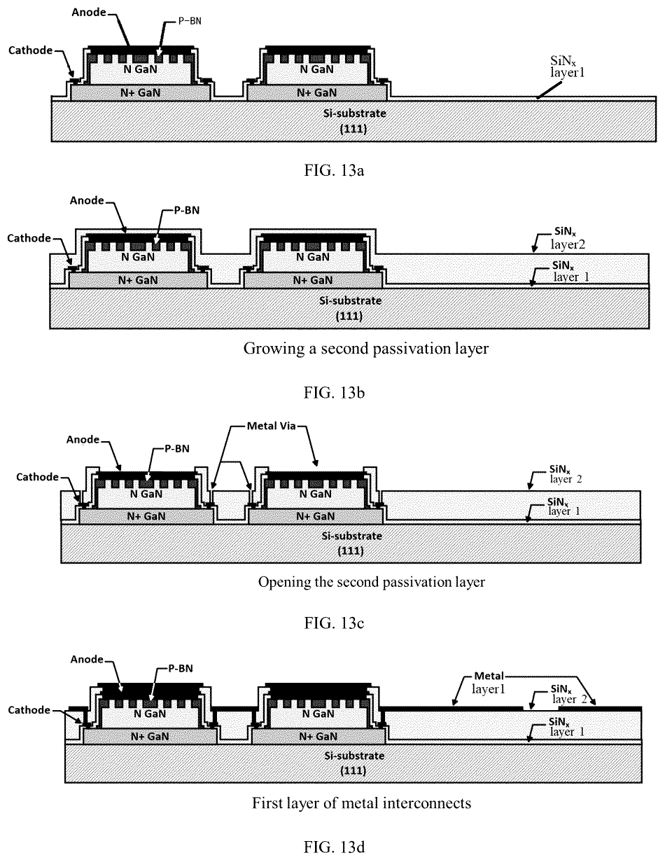

In the fourth aspect, the embodiments of the disclosure provide a preparation method of a monolithic integrated three-phase DRU, configured to prepare the monolithic integrated three-phase DRU as described in the third aspect. Please refer to FIG. 12, the preparation method of the monolithic integrated three-phase DRU includes the following steps S100-S300.

In S100, on a same Si substrate, multiple prepared quasi-vertical JBS diodes are obtained. Specifically, each quasi-vertical JBS diode is prepared by the preparation method of the quasi-vertical JBS diodes as described in the second aspect.

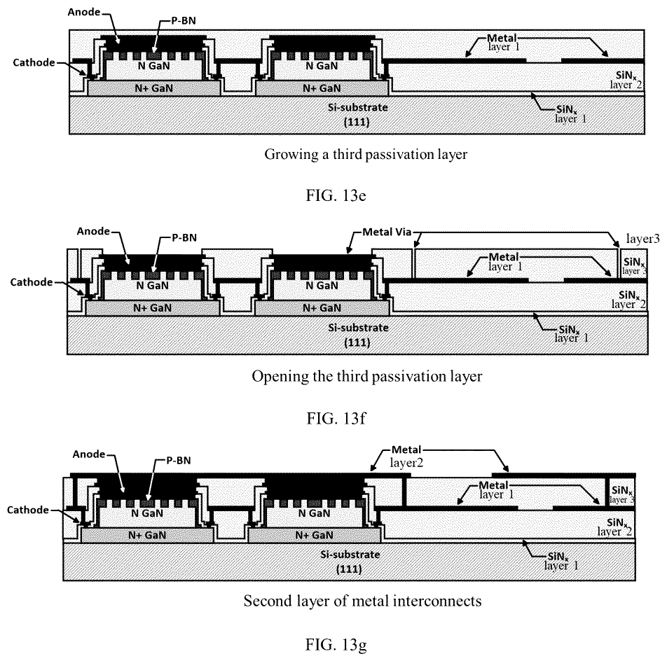

Specifically, please refer to the relevant content of the second aspect. The obtained single quasi-vertical JBS diode is shown in FIG. 5j. S100 is to prepare multiple quasi-vertical JBS diodes on the same Si substrate, the result is shown in FIG. 13a. SiNₓ represents the passivation layer, that is, the first passivation layer mentioned above. Layer1 represents the first layer.

In S200, a second passivation layer is grown on all exposed surfaces and sides of a multi-device structure on the Si substrate. First holes are opened by etching the second passivation layer, and the metal evaporation is performed on the first holes. A first layer of metal interconnects is formed according to an electrode connection requirement of the multiple quasi-vertical JBS diodes of the monolithic integrated three-phase DRU.

As shown in FIG. 13b, the second passivation layer is grown to cover all surfaces of the current structure.

Then as shown in FIG. 13c, holes are opened in the anode region and the cathode region respectively by etching the second passivation layer. Metal Via represents metal via.

Then, an anode metal is evaporated in the anode contact opening, and a cathode metal is evaporated in the cathode contact opening.

Specifically, the process parameters of S200 are consistent with the corresponding steps in the second aspect.

Finally, the first layer of metal interconnects is formed according to the electrode connection requirement of the multiple quasi-vertical JBS diodes of the monolithic integrated three-phase DRU, that is, a metal through-hole (i.e., metal via) is defined to connect with the first layer, as shown in FIG. 13d. The first layer of metal interconnects specifically connecting electrodes of which diode can be understood by referring to FIGS. 6 to 8. They will not be explained one by one here.

In S300, a third passivation layer is grown. Second holes are opened by etching the third passivation layer, and the metal evaporation is performed on the second holes. A second layer of metal interconnects is formed according to the electrode connection requirement of the multiple quasi-vertical JBS diodes of the monolithic integrated three-phase DRU.

As shown in FIG. 13e, the third passivation layer is grown to cover all surfaces of the current structure.

Then, as shown in FIG. 13f, holes are opened in the anode region and the cathode region respectively by etching the third passivation layer.

Then, an anode metal is evaporated in the anode contact opening, and a cathode metal is evaporated in the cathode contact opening. Specifically, the process parameters of S300 are consistent with S200.

Finally, the second layer of metal interconnects is formed according to the electrode connection requirement of the multiple quasi-vertical JBS diodes of the monolithic integrated three-phase DRU, that is, a metal through-hole (i.e., metal via) is defined to connect with the second layer, as shown in FIG. 13g. The second layer of metal interconnects specifically connecting electrodes of which diode can be understood by referring to FIGS. 6 to 8. They will not be explained one by one here.

The preparation method of the monolithic integrated three-phase DRU provided by the embodiments of the disclosure prepare multiple quasi-vertical JBS diodes on the same Si substrate based on the provided preparation method of the quasi-vertical JBS diode. Then, the passivation layer is grown on all exposed surfaces and sides of the multi-device structure on the Si substrate, holes are opened by etching the passivation layer, metal evaporation is performed in the holes, and the first layer of metal interconnects is formed according to the electrode connection requirement of the multiple quasi-vertical JBS diodes of the monolithic integrated three-phase DRU. Finally, the passivation layer is grown again, holes are opened by etching the passivation layer, metal evaporation is performed in the holes, and the second layer of metal interconnects is formed according to the electrode connection requirement of the multiple quasi-vertical JBS diodes of the monolithic integrated three-phase DRU, thereby preparing the monolithic integrated three-phase DRU. The monolithic integrated three-phase DRU is achieved based on the provided quasi-vertical JBS diode, which achieves an improvement in integration, greatly reduces the circuit volume, and can improve circuit reliability. Existing devices mostly use Si devices, while GaN devices can work stably under more complex working conditions compared to the Si devices. The excellent electrical properties and stability of the GaN devices are considered to be suitable for applications in high frequency, high power, strong radiation and other occasions. In the disclosure, the Si-based GaN quasi-vertical JBS diode based on the P-BN technology utilizes the high breakdown field strength of the BN material and the electric field regulation capability of the JBS structure to greatly improve the withstand voltage level of the Schottky diode, and broaden the voltage application window of the miniaturized DRU three-phase rectifier circuit. However, the related art mostly uses traditional Schottky diodes, lacks effective junction termination technology to increase the operating voltage of the device, and limits the working range of the existing devices.

It should be noted that, in the description of the disclosure, it should be understood that the terms “center”, “longitudinal”, “lateral”, “length”, “width”, “thickness”, “up”, “down”, “front”, “back”, “left”, “right”, “vertical”, “horizontal”, “top”, “bottom”, “inside”, “outside”, “clockwise”, “counterclockwise” and the like indicate orientations or positional relationships are based on the orientations or positional relationships shown in the drawings, and are merely for the convenience of describing the disclosure and simplifying the description, and do not indicate or imply that the referred device or element must have a specific orientation, be constructed and operated in a specific orientation, and therefore should not be understood as limiting the disclosure.

In addition, the terms “first” and “second” are used for descriptive purposes only and should not be understood as indicating or implying relative importance or implicitly indicating the number of the indicated technical features. Therefore, the features defined as “first” and “second” may explicitly or implicitly include one or more of the features. In the description of the disclosure, the meaning of “plurality”is two or more, unless otherwise clearly and specifically defined.

In the description of this specification, the description with reference to the terms “one embodiment”, “some embodiments”, “example”, “specific example”, or “some examples” means that the specific features, structures, materials or characteristics described in conjunction with the embodiment or example are included in at least one embodiment or example of the disclosure. In this specification, the schematic representations of the above terms do not necessarily refer to the same embodiment or example. Moreover, the specific features, structures, materials or characteristics described may be combined in any one or more embodiments or examples in a suitable manner. In addition, those skilled in the art may combine different embodiments or examples described in this specification.

The above descriptions are merely some of the embodiments of the disclosure, and is not used to limit a scope of protection of the disclosure. Any modification, equivalent replacement and improvement made within a spirit and a principle of the disclosure are included in the scope of protection of the disclosure.

1. A monolithic integrated three-phase diode rectifier unit (DRU), comprising:
a first alternating current (AC) input terminal (Port1), a second AC input terminal (Port2), a third AC input terminal (Port3), a first rectified direct current (DC) output terminal (Port4), a second rectified DC output terminal (Port5), and diode groups corresponding to six rectifier bridge arms, wherein the diode groups comprise: a first phase forward diode group (DG1), a first phase reverse diode group (DG2), a second phase forward diode group (DG3), a second phase reverse diode group (DG4), a third phase forward diode group (DG5), and a third phase reverse diode group (DG6);
wherein the first AC input terminal (Port1) is connected to an anode input terminal of the first phase forward diode group (DG1) and a cathode input terminal of the first phase reverse diode group (DG2);
wherein the second AC input terminal (Port2) is connected to an anode input terminal of the second phase forward diode group (DG3) and a cathode input terminal of the second phase reverse diode group (DG4);
wherein the third AC input terminal (Port3) is connected to an anode input terminal of the third phase forward diode group (DG5) and a cathode input terminal of the third phase reverse diode group (DG6);
wherein the first rectified DC output terminal (Port4) is connected to a cathode input terminal of the first phase forward diode group (DG1), a cathode input terminal of the second phase forward diode group (DG3) and a cathode input terminal of the third phase forward diode group (DG5);
wherein the second rectified DC output terminal (Port5) is connected to an anode input terminal of the first phase reverse diode group (DG2), an anode input terminal of the second phase reverse diode group (DG4) and an anode input terminal of the third phase reverse diode group (DG6); and
wherein diodes in each of the diode groups are connected in series in a same direction, and are the same in number, and each of the diodes in each of the diode groups is a quasi-vertical junction barrier Schottky (JBS) diode; the quasi-vertical JBS diode comprises: a silicon (Si) substrate, a n-type doping gallium nitride (N+ GaN) conductive layer and an N-type GaN drift layer sequentially disposed in that order from bottom to top; a top region of the N-type GaN drift layer defines groove structures distributed concentrically and annularly, and a magnesium-doped (Mg-doped) P-type boron nitride (BN) material is disposed on an inside of each of the groove structures and a side of the N-type GaN drift layer; an anode is disposed on a surface of the N-type GaN drift layer defining the groove structures; and a cathode is disposed on a surface of the N+ GaN conductive layer at intervals around the N-type GaN drift layer.

2. The monolithic integrated three-phase DRU as claimed in claim 1, wherein a doping concentration of Si in the N+ GaN conductive layer is in a range of 1.0×10¹⁸ per cubic centimeters (cm-3) to 1.0×10¹⁹ cm⁻³.

3. The monolithic integrated three-phase DRU as claimed in claim 1, wherein a doping concentration of Si in a non-groove structure part in the N-type GaN drift layer is in a range of 1.8×10¹⁵ cm⁻³ to 1.0×10¹⁷ cm⁻³.

4. The monolithic integrated three-phase DRU as claimed in claim 1, wherein a doping concentration of Mg in the Mg-doped P-type BN material is in a range of 1.7×10¹⁵ cm⁻³ to 5.0×10¹⁶ cm⁻³.

5. The monolithic integrated three-phase DRU as claimed in claim 1, wherein a depth of each of the groove structures is in a range of 0.5 microns (μm) to 4 μm, and a distance between the groove structures distributed concentrically and annularly is in a range of 1 μm to 2.5 μm.

6. The monolithic integrated three-phase DRU as claimed in claim 1, wherein a preparation method of the quasi-vertical JBS diode comprises:
obtaining an epitaxial layer structure, wherein the epitaxial layer structure comprises: the Si substrate, the N+ GaN conductive layer and the N-type GaN drift layer from bottom to top;
etching to remove an outer side of the N-type GaN drift layer to obtain a retained N-type GaN drift layer and an exposed N+ GaN conductive layer, so that the retained N-type GaN drift layer and the exposed N+ GaN conductive layer form a first step structure;
etching to remove an outer side of the N+ GaN conductive layer to obtain a retained N+ GaN conductive layer and an exposed Si substrate, so that the retained N+GaN conductive layer and the exposed Si substrate form a second step structure;
etching the groove structures distributed concentrically and annularly on the top region of the N-type GaN drift layer;
spattering the Mg-doped P-type BN material on the inside of each of the groove structures and the side of the N-type GaN drift layer by a magnetron sputtering process, followed by annealing treatment to obtain an annealed device; and removing excess Mg-doped P-type BN material from a surface of the annealed device;
growing a first passivation layer on all exposed surfaces and sides above an upper surface of the Si substrate;
removing the first passivation layer on a surface of the N-type GaN drift layer to define an anode contact opening, and removing the first passivation layer at predetermined positions on two sides of the N+ GaN conductive layer to define a cathode contact opening; and
forming the anode in the anode contact opening by metal evaporation, and forming the cathode with a distance surrounding the N-type GaN drift layer by the metal evaporation in the cathode contact opening.

7. The monolithic integrated three-phase DRU as claimed in claim 1, wherein a working process of the monolithic integrated three-phase DRU comprises:
in each cycle, according to a three-phase AC waveform input by the first AC input terminal (Port1), the second AC input terminal (Port2) and the third AC input terminal (Port3), and a circuit conducting state, rectifying input-side AC voltage into output-side DC voltage by using simultaneously conducted diode groups in each of six conduction intervals, and outputting the output-side DC voltage through the first rectified DC output terminal (Port4) and the second rectified DC output terminal (Port5); wherein each of the six conduction intervals has two diode groups with mutually positive and negative polarity.

8. The monolithic integrated three-phase DRU as claimed in claim 7, wherein in each of the six conduction intervals, the simultaneously conducted diode groups comprise:
in a first conduction interval T1, the first phase forward diode group (DG1) and the third phase reverse diode group (DG6) conducting;
in a second conduction interval T2, the second phase forward diode group (DG3) and the third phase reverse diode group (DG6) conducting;
in a third conduction interval T3, the second phase forward diode group (DG3) and the first phase reverse diode group (DG2) conducting;
in a fourth conduction interval T4, the third phase forward diode group (DG5) and the first phase reverse diode group (DG2) conducting;
in a fifth conduction interval T5, the third phase forward diode group (DG5) and the second phase reverse diode group (DG4) conducting; and
in a sixth conduction interval T6, the first phase forward diode group (DG1) and the second phase reverse diode group (DG4) conducting.

9. A preparation method of a monolithic integrated three-phase DRU, configured to prepare the monolithic integrated three-phase DRU as claimed in any one of claims 1-8, wherein the preparation method of the monolithic integrated three-phase DRU comprises:
acquiring a plurality of prepared quasi-vertical JBS diodes on a same Si substrate to obtain a multi-device structure; wherein each of the plurality of prepared quasi-vertical JBS diodes is prepared by the preparation method of the quasi-vertical JBS diode;
growing a second passivation layer on all exposed surfaces and sides of the multi-device structure on the Si substrate, opening first holes by etching the second passivation layer, performing the metal evaporation on the first holes, and forming a first layer of metal interconnects according to an electrode connection requirement of the plurality of prepared quasi-vertical JBS diodes of the monolithic integrated three-phase DRU; and
growing a third passivation layer, opening second holes by etching the third passivation layer, performing the metal evaporation on the second holes, and forming a second layer of metal interconnects according to the electrode connection requirement of the plurality of prepared quasi-vertical JBS diodes of the monolithic integrated three-phase DRU.
